(19) United States
(12) Patent Application Publication
(10) Pub. No.: US 2026/0372068 A1
(43) Pub. Date: Nov. 19, 2026

(54) SEMICONDUCTOR PACKAGE STRUCTURE

(71) Applicant: MEDIATEK INC., Hsinchu City (TW)

(72) Inventors: Shi-Bai CHEN, Hsinchu City (TW); Wei-Chih CHEN, Hsinchu City (TW)

(21) Appl. No.: 19/748,410

(22) Filed: Jul. 21, 2026

Related U.S. Application Data
(62) Division of application No. 18/472,453, filed on Sep. 22, 2023.
(60) Provisional application No. 63/380,073, filed on Oct. 19, 2022.

(51) Int. Cl. H10W 20/40; H10W 70/60; H10W 70/65; H10W 70/685; H10W 90/00

(52) U.S. Cl. CPC H10W 20/495; H10W 70/611; H10W 70/65; H10W 70/685; H10W 90/00; H10W 90/701; H10W 90/794

(57) ABSTRACT

A semiconductor package structure includes a capacitor substrate and a first semiconductor die. The capacitor substrate has a first surface and a second surface opposite the first surface and includes a first redistribution structure, a second redistribution structure, a through via, and a first capacitor structure. The first redistribution structure is disposed on the first surface. The second redistribution structure is disposed on the second surface. The through via electrically couples the first redistribution structure to the second redistribution structure. The first capacitor structure is disposed between the first redistribution structure and the second redistribution structure and is electrically coupled to the second redistribution structure. The first semiconductor die is disposed over the capacitor substrate and is electrically coupled to the first capacitor structure through the second redistribution structure.

### CROSS REFERENCE TO RELATED APPLICATIONS

This application is a Divisional of pending U.S. Utility Patent Application No. 18/472,453, filed on Sep. 22, 2023, which claims the benefit of U.S. Provisional Application No. 63/380,073 filed on Oct. 19, 2022, the entirety of which is incorporated by reference herein.

### BACKGROUND OF THE INVENTION

### Field of The Invention

The present invention relates to semiconductor technology, and, in particular, to a semiconductor package structure that includes a capacitor structure.

### Description of The Related Art

A semiconductor package structure can not only provide a semiconductor die with protection from environmental contaminants, but it can also provide an electrical connection between the semiconductor die packaged therein and a substrate, such as a printed circuit board (PCB).

Although existing semiconductor package structures generally meet requirements, they have not been satisfactory in all respects. For example, high active power induces thermal dissipation, and a current ramp is required for high-performance computing. Therefore, further improvements in semiconductor package structures are required.

### BRIEF SUMMARY OF THE INVENTION

Semiconductor package structures are provided. An exemplary embodiment of a semiconductor package structure includes a capacitor substrate and a first semiconductor die. The capacitor substrate has a first surface and a second surface opposite the first surface and includes a first redistribution structure, a second redistribution structure, a through via, and a first capacitor structure. The first redistribution structure is disposed on the first surface. The second redistribution structure is disposed on the second surface. The through via electrically couples the first redistribution structure to the second redistribution structure. The first capacitor structure is disposed between the first redistribution structure and the second redistribution structure and is electrically coupled to the second redistribution structure. The first semiconductor die is disposed over the capacitor substrate and is electrically coupled to the first capacitor structure through the second redistribution structure.

Another embodiment of a semiconductor package structure includes a substrate, a first capacitor structure, a capacitor substrate, and a first semiconductor die. The first capacitor structure is disposed over the substrate. The capacitor substrate is disposed over and is electrically coupled to the first capacitor structure. The capacitor substrate includes a semiconductor layer, a second capacitor structure, a redistribution structure, and a first through via. The second capacitor structure is embedded in the semiconductor layer. The redistribution structure is disposed over the semiconductor layer and is electrically coupled to the second capacitor structure. The first through via extends through the semiconductor layer. The first semiconductor die is disposed over the capacitor substrate and is electrically coupled to the second capacitor structure.

Yet another embodiment of a semiconductor package structure includes an interposer, a capacitor substrate, and a first semiconductor die. The interposer includes a first deep trench capacitor. The capacitor substrate is disposed over the interposer and includes a second deep trench capacitor, a redistribution structure, and a first through via. The redistribution structure is disposed over and is electrically coupled to the second deep trench capacitor. The first through via is adjacent to the second deep trench capacitor and is electrically coupled to the redistribution structure. The first semiconductor die is disposed over the capacitor substrate and is electrically coupled to the first deep trench capacitor and the second deep trench capacitor.

### BRIEF DESCRIPTION OF THE DRAWINGS

The present invention can be more fully understood by reading the subsequent detailed description and examples with references made to the accompanying drawings, wherein:

FIG. 1 is a cross-sectional view of an exemplary semiconductor package structure in accordance with some embodiments of the present disclosure;

FIG. 2 is a cross-sectional view of an exemplary semiconductor package structure in accordance with some embodiments of the present disclosure;

FIG. 3 is a cross-sectional view of a portion of an exemplary semiconductor package structure in accordance with some embodiments of the present disclosure; and

FIG. 4 is a cross-sectional view of an exemplary semiconductor package structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

Furthermore, the description of “a first element extending through a second element” may include embodiments in which the first element is disposed in the second element and extends from a side of the second element to an opposite side of the second element, wherein a surface of the first element may be substantially leveled with a surface of the second element, or a surface of the first element may be outside a surface of the second element.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

A semiconductor package structure including a capacitor substrate is described in accordance with some embodiments of the present disclosure. The capacitor substrate includes one or more capacitor structures to provide capacitance, so that the high active power and high current ramp requirements can be met.

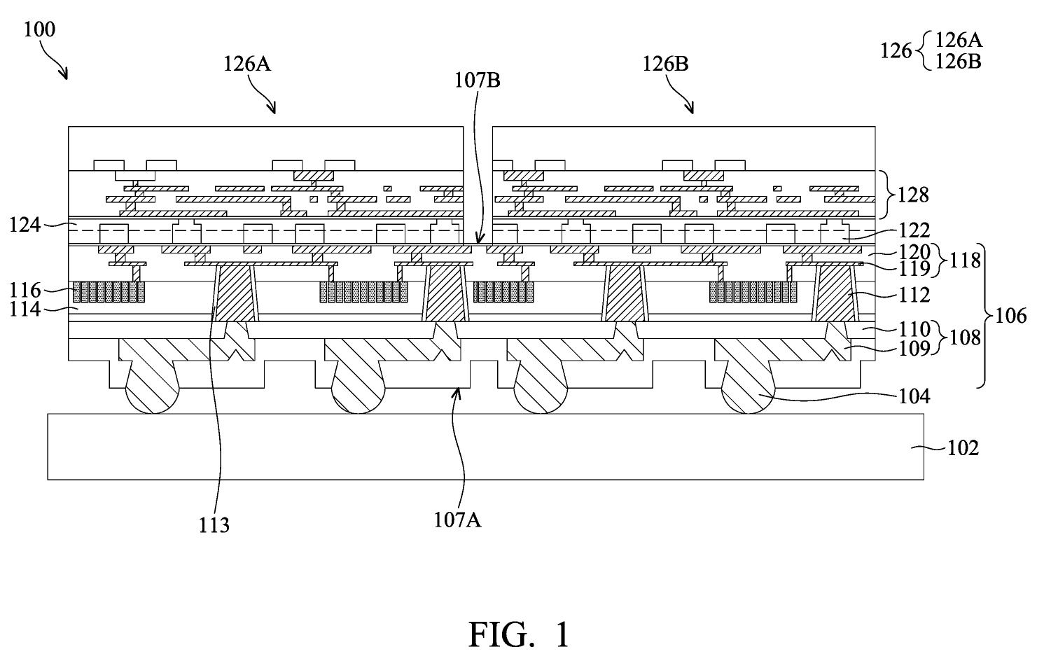

FIG. 1 is a cross-sectional view of a semiconductor package structure 100 in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As shown in FIG. 1, the semiconductor package structure 100 includes a substrate 102, in accordance with some embodiments. The substrate 102 may be a coreless substrate or a cored substrate to prevent the substrate 102 from warpage. The substrate 102 may have a wiring structure (not illustrated) therein. In some embodiments, the wiring structure includes conductive pads, conductive vias, conductive lines, conductive pillars, the like, or a combination thereof. The wiring structure may be formed of conductive materials, including metal (e.g., tungsten, titanium, tantalum, ruthenium, cobalt, copper, aluminum, platinum, tin, silver, gold), metallic compound (e.g., tantalum nitride, titanium nitride, tungsten nitride), the like, an alloy thereof, or a combination thereof.

The wiring structure may be disposed in dielectric layers. The dielectric layers may also be referred to as inter-metal dielectric (IMD) layers. In some embodiments, the dielectric layers may be formed of organic materials, such as a polymer base material, non-organic materials, including silicon nitride, silicon oxide, silicon oxynitride, the like, or a combination thereof.

It should be noted that the configuration of the substrate 102 shown in the figures is exemplary only and is not intended to limit the present disclosure. Any desired semiconductor element may be formed in and on the substrate 102. However, in order to simplify the diagram, only the flat substrate 102 is illustrated.

The semiconductor package structure 100 includes a capacitor substrate 106 disposed over the substrate 102 and electrically coupled to the wiring structure of the substrate 102 through a plurality of conductive structures 104, in accordance with some embodiments. The conductive structures 104 may include microbumps, controlled collapse chip connection (C4) bumps, solder balls, ball grid array (BGA) balls, the like, or a combination thereof.

The semiconductor package structure 100 may include an underfill material (not illustrated) disposed between the capacitor substrate 106 and the substrate 102. The underfill material may fill in gaps between the conductive structures 104 to provide structural support. In some embodiments, the underfill material is formed of polymer, such as epoxy. The underfill material may be dispensed with capillary force, and then may be cured through any suitable curing process.

As shown in FIG. 1, the capacitor substrate 106 may have a first surface 107A and a second surface 107B opposite the first surface 107A. The capacitor substrate 106 includes a first redistribution structure 108 disposed on the first surface 107A and a second redistribution structure 118 disposed on the second surface 107B, in accordance with some embodiments. The first redistribution structure 108 may include a wiring structure 109 in dielectric layers 110, and the second redistribution structure 118 may include a wiring structure 119 in dielectric layers 120.

The wiring structures 109 and 119 may include conductive pads, conductive vias, conductive lines, conductive pillars, the like, or a combination thereof. The wiring structures 109 and 119 may be formed of conductive materials, and the exemplary conductive materials are previously described. In some embodiments, the dielectric layers 110 and 120 may be formed of organic materials, such as a polymer base material, non-organic materials, including silicon nitride, silicon oxide, silicon oxynitride, the like, or a combination thereof.

The capacitor substrate 106 includes a semiconductor layer 114 disposed between the first redistribution structure 108 and the second redistribution structure 118, in accordance with some embodiments. As shown in FIG. 1, the sidewalls of the semiconductor layer 114 may be substantially coplanar with the sidewalls of the first redistribution structure 108 and the sidewalls of the second redistribution structure 118.

The semiconductor layer 114 may include a bulk semiconductor, a compound semiconductor, an alloy semiconductor, the like, or a combination thereof. The semiconductor layer 114 may be formed of any suitable semiconductor material, such as silicon or germanium. The semiconductor layer 114 may be doped (e.g., using p-type or n-type dopants) or undoped. For example, the p-type dopants may include boron, and the n-type dopants may include phosphorus or arsenic.

The capacitor substrate 106 includes one or more capacitor structures 116 embedded in the semiconductor layer 114, in accordance with some embodiments. The capacitor structures 116 may be deep trench capacitors, which may each include an interlayer dielectric layer between two electrode layers (not illustrated). The electrode layers may be formed of conductive materials, and the interlayer dielectric layer may be formed of silicon oxide, silicon nitride, silicon oxynitride, high-k dielectric materials (e.g., HfO₂, ZrO₂, La₂O₃, Al₂O₃, TiO₂), the like, or a combination thereof.

The capacitor substrate 106 includes one or more through vias 112 extending through the semiconductor layer 114 and electrically coupling the first redistribution structure 108 to the second redistribution structure 118, in accordance with some embodiments. The through vias 112 may be formed of conductive material, including copper, aluminum, nickel, gold, silver, the like, an alloy thereof, or a combination thereof. The through vias 112 may extend into the dielectric layers 120. As shown in FIG. 1, a width of the through vias 112 decreases in a direction from the first surface 107A toward the second surface 107B, in some embodiments.

The capacitor substrate 106 may include a liner layer 113 covering the sidewalls of the through vias 112, in accordance with some embodiments. The liner layer 113 may extend into the dielectric layers 120. In some embodiments, the liner layer 113 is formed of insulating material, including silicon oxide, silicon nitride, silicon oxynitride, the like, or a combination thereof. The capacitor substrate 106 may include a seed layer (not illustrated) disposed between the through vias 112 and the liner layer 113. The seed layer may include a titanium layer and a copper layer on the titanium layer. Alternatively, the seed layer may include a copper layer.

The semiconductor package structure 100 includes one or more semiconductor dies 126 (including 126A and 126B) disposed over the capacitor substrate 106, in accordance with some embodiments. In some embodiments, the semiconductor dies 126A and 126B each independently includes a system-on-chip (SoC) die, a logic device, a memory device, a radio frequency (RF) device, the like, or a combination thereof. For example, the semiconductor dies 126A and 126B may each include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or a combination thereof.

The semiconductor dies 126A and 126B may include the same or different devices. For example, the semiconductor package structure 100 may include more than two semiconductor dies. The semiconductor package structure 100 may also include one or more passive components disposed over the capacitor substrate 106, such as resistors, capacitors, or inductors.

The semiconductor dies 126A and 126B may be electrically coupled to the capacitor substrate 106 through hybrid bonding, which may be a combination of dielectric-to-dielectric bonding and conductor-to-conductor bonding. For example, the conductive pads 122 may be bonded to each other through conductor-to-conductor bonding, which may be metal-to-metal direct bonding, such as copper-to-copper direct bonding. For example, the dielectric layers 124 may be bonded to each other through dielectric-to-dielectric bonding. By employing the hybrid bonding, the finer bonding pitch can be used and no underfill needs to be dispensed.

As shown in FIG. 1, the sidewalls of the dielectric layers 124 may be substantially coplanar with the sidewalls of the capacitor substrate 106 and/or the sidewalls of the semiconductor dies 126A or 126B. In some embodiments, the dielectric layer 124 between the capacitor substrate 106 and the semiconductor die 126A are spaced apart from the dielectric layer 124 between the capacitor substrate 106 and the semiconductor die 126B. In these embodiments, a portion of the top surface of the capacitor substrate 106 may be exposed.

By disposing the capacitor substrate 106, which includes the capacitor structures 116, the capacitance of the semiconductor package structure 100 can be increased. Thus, the high active power and high current ramp requirements can be met. In addition, the capacitor substrate 106 includes the redistribution structure 118 can electrically couple the semiconductor dies 126 disposed thereon, which can integrate chiplets. Furthermore, the distance between the capacitor structures 116 and the semiconductor dies 126 can be reduced.

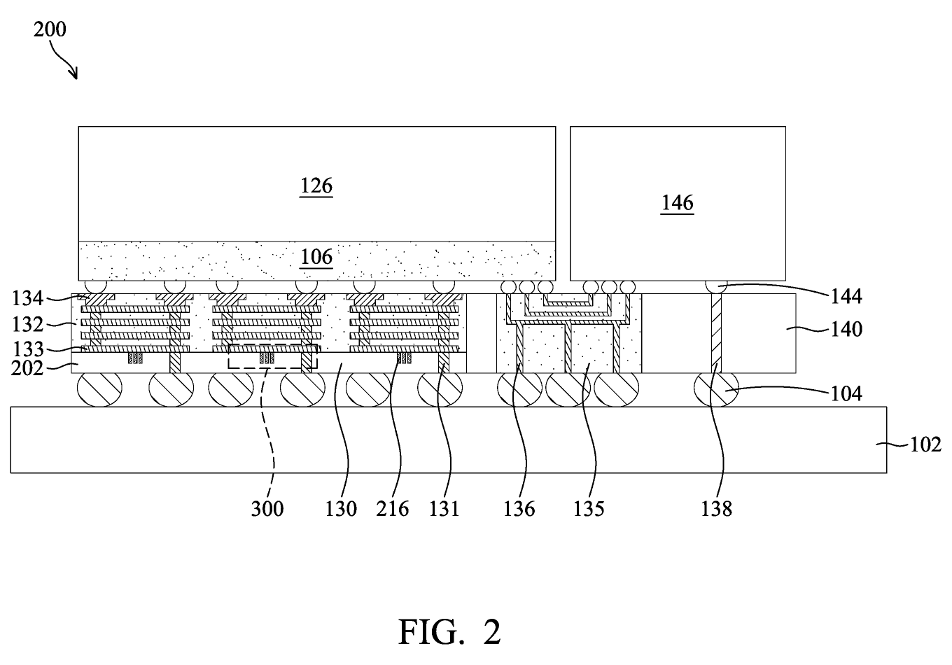

FIG. 2 is a cross-sectional view of a semiconductor package structure 200, in accordance with some embodiments of the disclosure. It should be noted that the semiconductor package structure 200 may include the same or similar components as that of the semiconductor package structure 100, which is illustrated in FIG. 1, and for the sake of simplicity, those components will not be discussed in detail again. In the following embodiments, the semiconductor package structure 200 includes additional capacitor structures.

As shown in FIG. 2, the semiconductor package structure 200 includes an embedded capacitor structure 202 disposed over the substrate 102, in accordance with some embodiments. The embedded capacitor structure 202 may include a semiconductor layer 130. The semiconductor layer 130 may be formed of any suitable semiconductor material, such as silicon or germanium. The semiconductor layer 130 may be doped (e.g., using p-type or n-type dopants) or undoped. For example, the p-type dopants may include boron, and the n-type dopants may include phosphorus or arsenic.

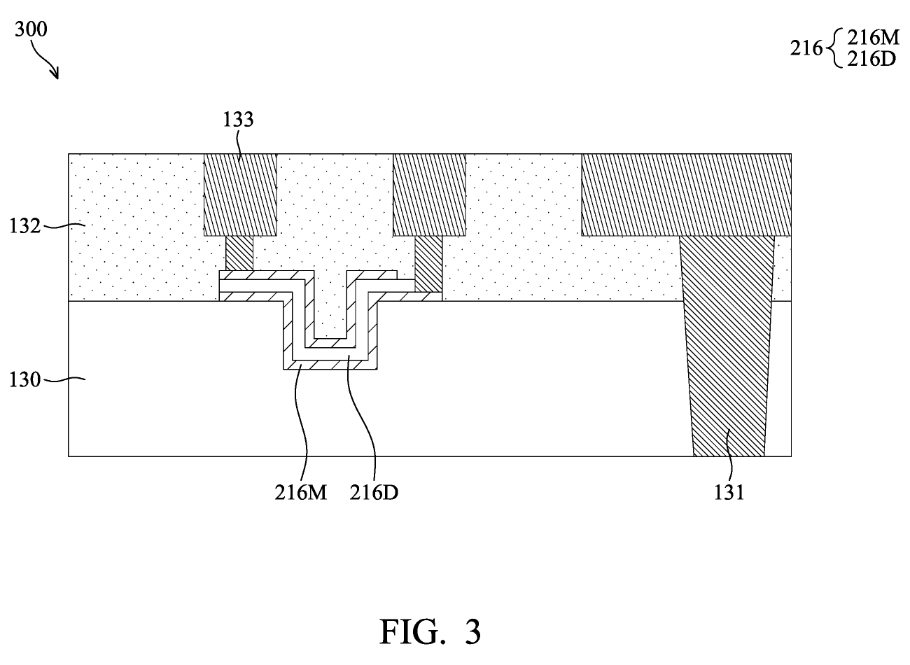

The embedded capacitor structure 202 includes one or more capacitor structures 216 in the semiconductor layer 130, in accordance with some embodiments. The capacitor structures 216 may be deep trench capacitors. A portion 300 of the semiconductor package structure 200 which includes the capacitor structures 216 will be described later with reference to FIG. 3.

The embedded capacitor structure 202 includes one or more through vias 131 adjacent to the capacitor structures 216, in accordance with some embodiments. The through vias 131 may extend through the semiconductor layer 130. The through vias 131 may be formed of conductive material, including copper, aluminum, nickel, gold, silver, the like, an alloy thereof, or a combination thereof.

The embedded capacitor structure 202 includes a wiring structure 133 disposed over the semiconductor layer 130 and electrically coupled to the capacitor structures 216 and the through vias 131, in accordance with some embodiments. The wiring structure 133 may include conductive pads, conductive vias, conductive lines, conductive pillars, the like, or a combination thereof.

The wiring structure 133 may be disposed in dielectric layers 132. The dielectric layers 132 may be formed of organic materials, such as a polymer base material, non-organic materials, including silicon nitride, silicon oxide, silicon oxynitride, the like, or a combination thereof.

A plurality of conductive pads 134 are disposed over the wiring structure 133 to electrically couple to the wiring structure 133, in accordance with some embodiments. The conductive pads 134 may be formed of conductive material, including copper, aluminum, nickel, gold, silver, the like, an alloy thereof, or a combination thereof.

The semiconductor package structure 200 includes an interconnect structure 135 adjacent to the embedded capacitor structure 202, in accordance with some embodiments. The interconnect structure 135 may include a wiring structure 136 therein. In some embodiments, the wiring structure 136 includes conductive pads, conductive vias, conductive lines, conductive pillars, the like, or a combination thereof.

The interconnect structure 135 may electrically couple the capacitor substrate 106 to a semiconductor die 146. The semiconductor die 146 may include the components discussed above with respect to the semiconductor dies 126, and will not be repeated. The semiconductor dies 146 and 126 may include the same or different devices.

A molding material 140 surrounds the embedded capacitor structure 202 and the interconnect structure 135, in accordance with some embodiments. The molding material 140 may protect the embedded capacitor structure 202 and the interconnect structure 135 from the environment, thereby preventing them from damage due to stress, chemicals, and moisture. The molding material 140 may separate the embedded capacitor structure 202 from the interconnect structure 135. The molding material 140 may be formed of a nonconductive material, including moldable polymer, epoxy, resin, the like, or a combination thereof.

One interconnect structure 135 is shown for illustrative purposes only, and there may be more than one interconnect structures. According to some embodiments, the semiconductor package structure 200 includes more than one interconnect structures 135, and these interconnect structures 135 may be surrounded and spaced apart by the molding material 140. In addition, the semiconductor package structure 200 may include more than two semiconductor dies and one or more passive components over the molding material 140, such as resistors, capacitors, or inductors.

One or more through vias 132 are disposed in the molding material 140, in accordance with some embodiments. The through vias 138 may extend through the molding material 140. The through vias 138 may be similar to the through vias 112 as illustrated in FIG. 1, and will not be repeated.

The semiconductor package structure 200 includes a plurality of conductive structures 144 disposed over the molding material 140 and a plurality of conductive structures 104 disposed below the molding material 140, in accordance with some embodiments. The conductive structures 104 and 144 may each independently include microbumps, controlled collapse chip connection (C4) bumps, solder balls, ball grid array (BGA) balls, the like, or a combination thereof. The capacitor substrate 106 and the semiconductor die 146 may be electrically coupled to the substrate 102 through the embedded capacitor structure 202, the interconnect structure 135, the through vias 138, and the conductive structures 104, 144.

By disposing the capacitor structures 216, the capacitance of the semiconductor package structure 200 can be further increased. Furthermore, the interconnect structure 135 can electrically couple the capacitor substrate 106 and the capacitor structures 216 to one or more semiconductor dies, such as the semiconductor die 146.

FIG. 3 is a cross-sectional view of the portion 300 of the semiconductor package structure 200, in accordance with some embodiments of the disclosure. As shown in FIG. 3, each of the capacitor structures 216 includes an interlayer dielectric layer 216D sandwiched between two electrode layers 216M, in accordance with some embodiments. The electrode layers 216M may be formed of conductive materials, such as metal. The interlayer dielectric layer 216D may be formed of silicon oxide, silicon nitride, silicon oxynitride, high-k dielectric materials (e.g., HfO₂, ZrO₂, La₂O₃, Al₂O₃, TiO₂), the like, or a combination thereof.

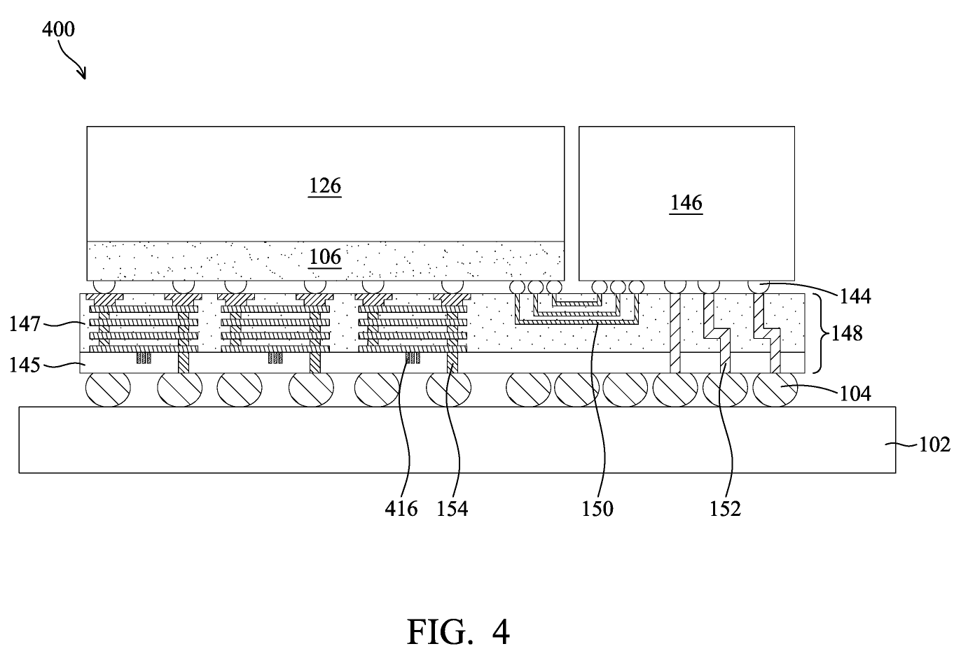

FIG. 4 is a cross-sectional view of a semiconductor package structure 400, in accordance with some embodiments of the disclosure. It should be noted that the semiconductor package structure 400 may include the same or similar components as that of the semiconductor package structure 200, which is illustrated in FIG. 2, and for the sake of simplicity, those components will not be discussed in detail again. In the following embodiments, the semiconductor package structure 400 includes an interposer with capacitor structures.

As shown in FIG. 4, the semiconductor package structure 400 includes an interposer 148 disposed over the substrate 102, in accordance with some embodiments. The interposer 148 may include a bulk semiconductor, a compound semiconductor, an alloy semiconductor, the like, or a combination thereof. The interposer 148 may be formed of any suitable semiconductor material, such as silicon or germanium.

The interposer 148 may include a semiconductor layer 145. The semiconductor layer 145 may be formed of any suitable semiconductor material, such as silicon or germanium. The semiconductor layer 145 may be doped (e.g., using p-type or n-type dopants) or undoped. For example, the p-type dopants may include boron, and the n-type dopants may include phosphorus or arsenic.

The semiconductor package structure 400 includes one or more capacitor structures 416 embedded in the semiconductor layer 145, in accordance with some embodiments. The capacitor structures 416 may be deep trench capacitors. The capacitor structures 416 may include the components discussed above with respect to the capacitor structures 216 as illustrated in FIG. 2, and will not be repeated.

The interposer 148 may include dielectric layers 147 disposed over the semiconductor layer 145. The dielectric layers 147 may be formed of organic materials, such as a polymer base material, non-organic materials, including silicon nitride, silicon oxide, silicon oxynitride, the like, or a combination thereof.

A wiring structure 154 may be disposed over the capacitor structures 416. The wiring structure 154 may include the components discussed above with respect to the wiring structure 133 and the through vias 131 as illustrated in FIG. 2, and will not be repeated.

The interposer 148 may include a wiring structure 150 between the capacitor substrate 106 and the semiconductor die 146 to electrically couple the capacitor substrate 106 to the semiconductor die 146. In some embodiments, the wiring structure 150 includes conductive pads, conductive vias, conductive lines, conductive pillars, the like, or a combination thereof. The semiconductor dies 146 and 126 may include the same or different devices. In addition, the semiconductor package structure 400 may include more than two semiconductor dies, and may also include one or more passive components disposed over the interposer 148, such as resistors, capacitors, or inductors.

The semiconductor package structure 400 includes one or more through vias 152 extending through the interposer 148, in accordance with some embodiments. The through vias 152 may be similar to the through vias 138 as illustrated in FIG. 2, and will not be repeated.

The semiconductor package structure 400 includes a plurality of conductive structures 144 disposed over the interposer 148 and a plurality of conductive structures 104 disposed below the interposer 148, in accordance with some embodiments. The conductive structures 104 and 144 may each independently include microbumps, controlled collapse chip connection (C4) bumps, solder balls, ball grid array (BGA) balls, the like, or a combination thereof. The capacitor substrate 106 and the semiconductor die 146 may be electrically coupled to the substrate 102 through the interposer 148 and the conductive structures 104, 144.

By disposing the interposer 148 including the capacitor structures 416, the capacitance of the semiconductor package structure 400 can be further increased. Furthermore, the wiring structure 150 in the interposer 148 can electrically couple the capacitor substrate 106 and the capacitor structures 416 to one or more additional semiconductor dies, such as the semiconductor die 146.

In summary, the semiconductor package structure according to the present disclosure includes a capacitor substrate, which includes one or more capacitor structures, to provide capacitance. As a result, the high active power and high current ramp requirements can be met. In addition, the capacitor substrate includes redistribution structures to electrically couple semiconductor dies disposed thereon, so that chiplet integration can be obtained. Furthermore, the distance between the capacitor structures and the semiconductor dies can be shortened.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a capacitor substrate having a first surface and a second surface opposite the first surface and comprising:
a first redistribution structure disposed on the first surface;
a second redistribution structure disposed on the second surface;
a through via electrically coupling the first redistribution structure to the second redistribution structure; and
a first capacitor structure disposed between the first redistribution structure and the second redistribution structure and electrically coupled to the second redistribution structure; and
a first semiconductor die disposed over the capacitor substrate and electrically coupled to the first capacitor structure through the second redistribution structure.

2. The semiconductor package structure as claimed in claim 1, further comprising a hybrid bonding electrically coupling the first semiconductor die to the second redistribution structure.

3. The semiconductor package structure as claimed in claim 2, wherein the hybrid bonding has a sidewall substantially coplanar with a sidewall of the capacitor substrate.

4. The semiconductor package structure as claimed in claim 1, wherein the capacitor substrate further comprises a semiconductor layer sandwiched between the first redistribution structure and the second redistribution structure, and the first capacitor structure is disposed in the semiconductor layer.

5. The semiconductor package structure as claimed in claim 4, wherein the semiconductor layer has a sidewall substantially coplanar with a sidewall of the first redistribution structure.

6. The semiconductor package structure as claimed in claim 1, further comprising an interconnect structure disposed below the capacitor substrate and electrically coupling the capacitor substrate to a second semiconductor die.

7. The semiconductor package structure as claimed in claim 6, further comprising:
a second capacitor structure adjacent to the interconnect structure; and
a molding material surrounding the second capacitor structure and the interconnect structure.

8. The semiconductor package structure as claimed in claim 1, further comprising an interposer disposed below the capacitor substrate and comprising a second capacitor structure, wherein the interposer electrically couples the capacitor substrate to a second semiconductor die.

9. A semiconductor package structure, comprising:
a substrate;
a first capacitor structure disposed over the substrate;
a capacitor substrate disposed over and electrically coupled to the first capacitor structure, wherein the capacitor substrate comprises:
a semiconductor layer;
a second capacitor structure embedded in the semiconductor layer;
a redistribution structure disposed over the semiconductor layer and electrically coupled to the second capacitor structure; and
a first through via extending through the semiconductor layer; and
a first semiconductor die disposed over the capacitor substrate and electrically coupled to the second capacitor structure.

10. The semiconductor package structure as claimed in claim 9, further comprising a second semiconductor die adjacent to the first semiconductor die and electrically coupled to the redistribution structure.

11. The semiconductor package structure as claimed in claim 10, further comprising a hybrid bonding electrically coupling the redistribution structure to the first semiconductor die and the second semiconductor die.

12. The semiconductor package structure as claimed in claim 10, further comprising an interconnect structure adjacent to the first capacitor structure and electrically coupling the capacitor substrate to a third semiconductor die.

13. The semiconductor package structure as claimed in claim 12, further comprising a molding material surrounding the first capacitor structure and the interconnect structure and separating the first capacitor structure from the interconnect structure.

14. The semiconductor package structure as claimed in claim 13, further comprising a second through via extending through the molding material and electrically coupled to the substrate.

15. The semiconductor package structure as claimed in claim 9, wherein the first capacitor structure is disposed in an interposer, and the interposer further comprises a second through via adjacent to the first capacitor structure and electrically coupled to the substrate.
